(19) United States
(12) Patent Application Publication
(10) Pub. No.: US 2024/0120369 A1
(43) Pub. Date: Apr. 11, 2024

(54) HIGH DENSITY TRENCH CAPACITOR

(71) Applicant: International Business Machines Corporation, Armonk, NY (US)

(72) Inventors: Ruilong Xie, Niskayuna, NY (US); Julien Frougier, Albany, NY (US); Kangguo Cheng, Schenectady, NY (US); Chanro Park, Clifton Park, NY (US); Min Gyu Sung, Latham, NY (US)

(21) Appl. No.: 17/961,774

(22) Filed: Oct. 7, 2022

(51) Int. Cl. H01L 49/02

(52) U.S. Cl. CPC H01L 28/91

(57) ABSTRACT

A semiconductor structure includes a capacitor structure at least partially disposed in a trench of an interlayer dielectric layer. The capacitor structure includes first and second electrode layers separated by a dielectric layer. A top surface of the first electrode layer is below a top surface of the second electrode layer and the dielectric layer. A spacer is disposed on the first electrode layer and a contact is disposed in the trench and connected to the second electrode layer and the spacer.

### BACKGROUND

Semiconductor manufacturing and processes utilize trench capacitors for many applications including, for example, as decoupling capacitors, charge storage capacitors and memory capacitors. As miniaturization of semiconductor devices progresses, the feature size of the storage trench for the trench capacitor has been correspondingly minimized.

### SUMMARY

In an illustrative embodiment, a semiconductor structure comprises a capacitor structure at least partially disposed in a trench of an interlayer dielectric layer. The capacitor structure comprises first and second electrode layers separated by a dielectric layer. A top surface of the first electrode layer being below a top surface of the second electrode layer and the dielectric layer. The capacitor structure further comprises a spacer disposed on the first electrode layer and a contact disposed in the trench and connected to the second electrode layer and the spacer.

In accordance with another illustrative embodiment, a semiconductor structure comprises a capacitor structure at least partially disposed in a trench of an interlayer dielectric layer. The capacitor structure comprises first and second electrode layers separated by a dielectric layer. A top surface of the second electrode layer being below a top surface of the first electrode layer and the dielectric layer. The capacitor structure further comprises a spacer disposed on the second electrode layer and a contact disposed in the trench and connected to the first electrode layer and the spacer.

In accordance with yet another illustrative embodiment, a semiconductor structure comprises a capacitor structure at least partially disposed in a trench of an interlayer dielectric layer. The capacitor structure comprises a plurality of first and second electrode layers arranged in alternating relation with each other and having a dielectric layer disposed between adjacent first and second electrode layers. The plurality of first electrode layers, the plurality of second electrode layers and the dielectric layer are in a u-shaped configuration, with one of the plurality of first electrode layers and the plurality of second electrode layers having a top surface below a top surface of the other one of the plurality of first electrode layers and the plurality of second electrode layers. The capacitor structure further comprises a spacer on the top surface of the respective one of the plurality of first electrode layers and the plurality of second electrode layers having the top surface below the top surface of the other one of the plurality of first electrode layers and the plurality of second electrode layers; and a contact disposed in the trench and connected to the other one of the plurality of first electrode layers and the plurality of second electrode layers and the spacer.

### BRIEF DESCRIPTION OF THE DRAWINGS

FIG. 1A is a top plan view of a semiconductor structure at a first intermediate stage of fabrication, according to one or more illustrative embodiments.

FIG. 1B is a side-cross-sectional view taken along the line X1-X1 of FIG. 1A of the semiconductor structure at the first intermediate stage of fabrication illustrating the first trench within the substrate, according to one or more illustrative embodiments.

FIG. 2 is a side-cross-sectional view taken along the line X1-X1 of FIG. 1A of the semiconductor structure at a second intermediate stage of fabrication, according to one or more illustrative embodiments.

FIG. 3 is a side-cross-sectional view taken along the line X1-X1 of FIG. 1A of the semiconductor structure at a third intermediate stage of fabrication, according to one or more illustrative embodiments.

FIG. 4 is a side-cross-sectional view taken along the line X1-X1 of FIG. 1A of the semiconductor structure at a fourth intermediate stage of fabrication, according to one or more illustrative embodiments.

FIG. 5 is a side-cross-sectional view taken along the line X1-X1 of FIG. 1A of the semiconductor structure at a fifth intermediate stage of fabrication, according to one or more illustrative embodiments.

FIG. 6A is a top plan view of the semiconductor structure at a sixth intermediate stage of fabrication illustrating formation of a first contact recess in the dielectric layer of the semiconductor structure for a first electrode contact adjacent the first trench capacitor structure, according to one or more illustrative embodiments.

FIG. 6B is a side-cross-sectional view taken along the line X1-X1 of FIG. 6A of the semiconductor structure at the sixth intermediate stage of fabrication, according to one or more illustrative embodiments.

FIG. 6C is a side-cross-sectional view taken along the line X2-X2 of FIG. 6A of the semiconductor structure at the sixth intermediate stage of fabrication, according to one or more illustrative embodiments.

FIG. 7A is a top plan view of the semiconductor structure at a seventh intermediate stage of fabrication according to one or more illustrative embodiments.

FIG. 7B is a side cross-sectional view taken along the line X1-X1 of FIG. 7A of the semiconductor structure at the seventh intermediate stage of fabrication illustrating selective recessing of the first electrode layers of the first trench capacitor structure within the first contact recess, according to one or more illustrative embodiments.

FIG. 7C is a side cross-sectional view taken along the line X2-X2 of FIG. 7A of the semiconductor structure at the seventh intermediate stage of fabrication illustrating selective recessing of the first electrode layers of the first trench capacitor structure within the first contact recess, according to one or more illustrative embodiments.

FIG. 8A is a top plan view of the semiconductor structure at an eighth intermediate stage of fabrication illustrating formation of a second contact recess in the dielectric layer of the semiconductor structure for a second electrode contact adjacent the trench capacitor structure, according to one or more illustrative embodiments.

FIG. 8B is a side-cross-sectional view taken along the line X1-X1 of FIG. 8A of the semiconductor structure at the eighth intermediate stage of fabrication, according to one or more illustrative embodiments.

FIG. 8C is a side-cross-sectional view taken along the line X2-X2 of FIG. 8A of the semiconductor structure at the eighth intermediate stage of fabrication, according to one or more illustrative embodiments.

FIG. 9A is a top plan view of the semiconductor structure at a ninth intermediate stage of fabrication, according to one or more illustrative embodiments.

FIG. 9B is a side cross-sectional view taken along the line X1-X1 of FIG. 9A of the semiconductor structure at the ninth intermediate stage of fabrication illustrating selective recessing of the second electrode layers of the trench capacitor structure within the second contact recess, according to one or more illustrative embodiments.

FIG. 9C is a side cross-sectional view taken along the line X2-X2 of FIG. 9A of the semiconductor structure at the ninth intermediate stage of fabrication illustrating selective recessing of the second electrode layers of the trench capacitor structure within the second contact recess, according to one or more illustrative embodiments.

FIG. 10A is a top plan view of the semiconductor structure at a tenth intermediate stage of fabrication, according to one or more illustrative embodiments.

FIG. 10B is a side cross-sectional view taken along the line X1-X1 of FIG. 10A of the semiconductor structure at the tenth intermediate stage of fabrication illustrating the first and second contact recesses and recesses formed in the first and second electrode layers of the trench capacitor structure, according to one or more illustrative embodiments.

FIG. 10C is a side cross-sectional view taken along the line X2-X2 of FIG. 10A of the semiconductor structure at the tenth intermediate stage of fabrication illustrating the first and second contact recesses and recesses formed in the first and second electrode layers of the trench capacitor structure, according to one or more illustrative embodiments.

FIG. 11A is a top plan view of the semiconductor structure at an eleventh intermediate stage of fabrication, according to one or more illustrative embodiments.

FIG. 11B is a side cross-sectional view taken along the line X1-X1 of FIG. 11A of the semiconductor structure at the eleventh intermediate stage of fabrication illustrating formation of inner spacers within the recesses formed in the first and second electrode layers of the trench capacitor structure, according to one or more illustrative embodiments.

FIG. 11C is a side cross-sectional view taken along the line X2-X2 of FIG. 11A of the semiconductor structure at the eleventh intermediate stage of fabrication illustrating formation of inner spacers within the recesses formed in the first and second electrode layers of the trench capacitor structure, according to one or more illustrative embodiments.

FIG. 12A is a top plan view of the semiconductor structure at a twelfth intermediate stage of fabrication subsequent to metallization, according to one or more illustrative embodiments.

FIG. 12B is a cross-sectional view taken along the line X1-X1 of FIG. 12A illustrating formation of a first contact connected to the capacitor structure, according to one or more illustrative embodiments.

FIG. 12C is a cross-sectional view taken along the line X2-X2 of 12A illustrating formation of a second contact connected to the capacitor structure, according to one or more illustrative embodiments.

FIG. 13 is a view similar to the view of FIG. 11C illustrating an alternate embodiment associated with the eleventh stage of fabrication of the semiconductor structure, according to one or more illustrative embodiments.

### DETAILED DESCRIPTION

Illustrative embodiments of the disclosure will now be described with regard to methods for fabricating semiconductor structures, as well as semiconductor devices comprising at least one field effect transistor and at least one trench capacitor, including, for example, a metal-to metal (MIM) capacitor.

In general, the various processes used to form a semiconductor structure fall into four general categories, namely, film deposition, removal/etching, semiconductor doping and patterning/lithography. Deposition is any process that grows, coats, or otherwise transfers a material onto a semiconductor device. Available technologies include physical vapor deposition (PVD), chemical vapor deposition (CVD), electrochemical deposition (ECD), molecular beam epitaxy (MBE) and, more recently, atomic layer deposition (ALD) among others. Removal/etching is any process that removes material from the semiconductor structure. Examples include etch processes (either wet or dry), and chemical-mechanical planarization (CMP), and the like. Semiconductor doping is the modification of electrical properties by doping, for example, transistor sources and drains, generally by diffusion and/or by ion implantation. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to an underlying substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the substrate, for example, a wafer, is aligned to the previously formed patterns and slowly the conductors, insulators and selectively doped regions are built up to form the final device.

The various layers, structures, and regions shown in the accompanying drawings are schematic illustrations that are not drawn to scale. In addition, for ease of explanation, one or more layers, structures, and regions of a type commonly used to form semiconductor devices or structures may not be explicitly shown in a given drawing. This does not imply that any layers, structures, and regions not explicitly shown are omitted from the actual semiconductor structures. Furthermore, the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, e.g., wet cleaning and annealing steps, are purposefully not described herein for economy of description.

Moreover, the same or similar reference numbers are used throughout the drawings to denote the same or similar features, elements, or structures, and thus, a detailed explanation of the same or similar features, elements, or structures will not be repeated for each of the drawings. The terms “about” or “substantially” as used herein with regard to thicknesses, widths, percentages, ranges, etc., are meant to denote being close or approximate to, but not exactly. For example, the term “about” or “substantially” as used herein implies that a small margin of error is present. Further, the terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or Y-direction of the Cartesian coordinates shown in the drawings.

Additionally, the term “illustrative” is used herein to mean “serving as an example, instance or illustration.” Any embodiment or design described herein is intended to be “illustrative” and is not necessarily to be construed as preferred or advantageous over other embodiments or designs. The term “connection” can include both an indirect “connection” and a direct “connection.” The terms “on” or “onto” with respect to placement of components relative to the semiconductor structure is not to be interpreted as requiring direct contact of the components for it is possible one or more intermediate components, layers or coatings may be positioned between the select components unless otherwise specified. More specifically, positional relationships, unless specified otherwise, can be direct or indirect, and the present disclosure is not intended to be limiting in this respect.

As previously noted herein, for the sake of brevity, conventional techniques related to semiconductor device and trench capacitor fabrication may or may not be described in detail herein. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor structure including the package integrated circuit according to illustrative embodiments utilize a variety of individually known physical and chemical processes performed on a semiconductor (e.g., silicon) substrate, some of which are described in the immediately following paragraphs.

In the discussion that follows, the semiconductor structure, which will incorporate one or more integrated circuit devices, will be referred to as the “semiconductor structure 10” throughout the various intermediate stages of fabrication, as represented in all the accompanying drawings.

As noted above, semiconductor manufacturing and processes utilize trench capacitors for many applications including, for example, as decoupling capacitors, charge storage capacitors and memory capacitors. As miniaturization of semiconductor devices progresses, the feature size of the storage trench for the trench capacitor has correspondingly minimized. The capacitance capabilities of trench capacitors are dependent upon trench length and trench depth. However, formation of trenches and introducing trench capacitors, particularly, for high density metal insulator metal (MIM) capacitors, provides substantial challenges during manufacture.

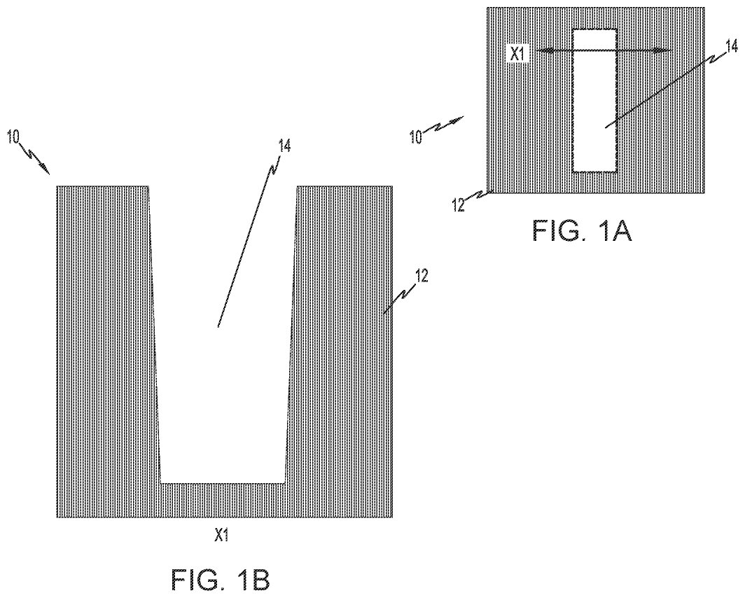

The non-limiting illustrative embodiments disclosed herein overcome the foregoing drawings. Referring now to FIGS. 1A-13, FIGS. 1A-1B schematically illustrate a first intermediate stage of fabrication of the semiconductor structure 10. The semiconductor structure 10 includes interlayer dielectric layer 12 with a trench 14 formed therein. The interlayer dielectric layer 12 may be fabricated from any suitable interlayer dielectric material such as, for example, SiO₂, SiN, SiBCN, SiOCN, SiC, SiOC, SiON, AlNx, AlOx, low-k dielectric, etc.

The trench 14 in which the trench capacitor will be deposited is formed by conventional lithographic and etching processes including dry and/or wet etching processes or combinations thereof.

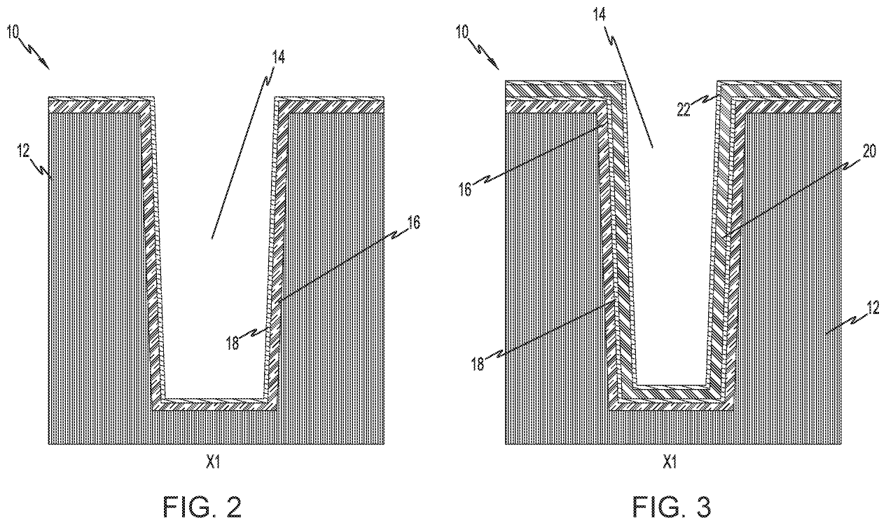

FIG. 2 illustrates a second intermediate stage of fabrication of the semiconductor structure 10 depicting a cross-sectional view similar to the view of FIG. 1B. A first conductive layer 16 is deposited within the trench 14, including the base and sidewalls of the trench 14, and also onto the interlayer dielectric layer 12. The first conductive layer 16 may include any suitable electrically conductive material. Representative examples of suitable materials for the first conductive layer 16 include, but are not limited to, polysilicon, metals, metal nitrides, metal alloys or combinations thereof. The first conductive layer 16 may be a single layer structure or contain multiple layers.

Following formation of the first conductive layer 16, a first dielectric layer 18 is formed on the first conductive layer 16 (also known as first electrode layer). The first dielectric layer 18 may include any suitable dielectric material such as, for example, silicon oxide (e.g., SiO₂), silicon nitride (e.g., Si₃N₄), SiON, SiC, SiOC, high-k dielectric such as HfO₂, ZrO₂, HfZrO₂, etc., or a combination thereof. The first dielectric layer 18 may be formed using any conventional deposition technique such as CVD, ALD, high density plasma CVD, sputtering, or any other suitable method, or combination of methods, for forming a generally conformal dielectric layer on the first conductive layer 16. The first dielectric layer 18 may be a single layer or contain multiple layers.

FIG. 3 illustrates a third intermediate stage of fabrication of the semiconductor structure 10. A second conductive layer 20 (also known as second electrode layer) is deposited on the first dielectric layer 18 followed by deposition of a second dielectric layer 22 onto the second conductive layer 20. Formation of the second conductive layer 20 and the second dielectric layer 22 includes any of the aforementioned processes. In illustrative embodiments, the second conductive layer 20 comprises a conductive material which is different from the first conductive layer 16. Suitable conductive material for first and second conductive layers 16 and 20 include, for example, TiN, TiC, TiAlC, W, TaN, Ru, Al, etc.

Similarly, the second dielectric layer 22 may include the dielectric materials and structures described in connection with the first dielectric layer 18 and deposited in accordance with the same processes. In illustrative embodiments, the second dielectric layer 22 comprises the same material as the first dielectric layer 18. In other illustrative embodiments, the second dielectric layer 22 exhibits a different structure than that of the first dielectric layer 18. Suitable dielectric material for second dielectric layer 22 can be any of those discussed above for first dielectric layer 18.

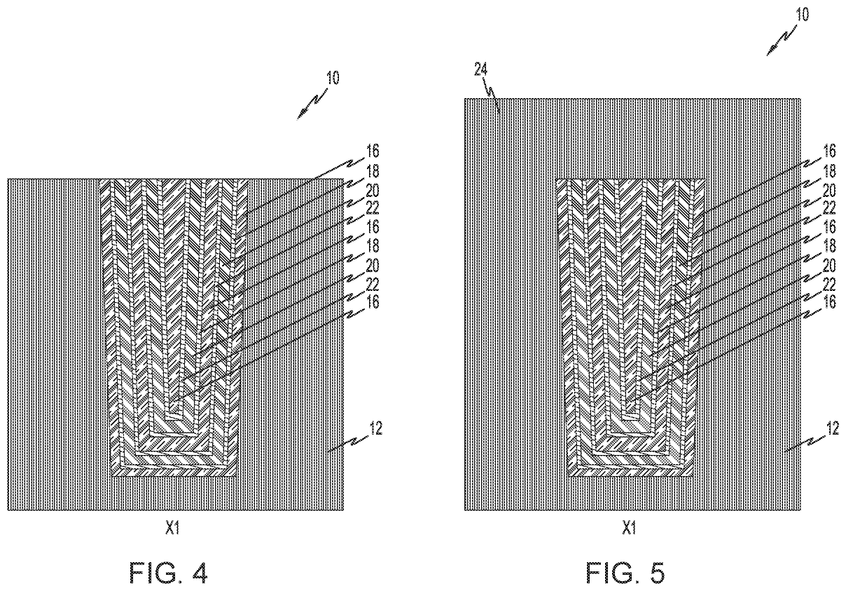

FIG. 4 illustrates a fourth intermediate stage of fabrication of the semiconductor structure 10. The steps associated with the second and third intermediate stages may be repeated one or more times to sequentially form one or more alternating or repeating arrangements of one or more sets of first and second conductive layers 16 and 20 and first and second dielectric layers 18 and 22 within the trench 14 and onto the interlayer dielectric layer 12 to fill the trench. The trench capacitor structure formed thereby contains a predetermined number of conductive and dielectric layers 16, 18, 20, 22 which, in combination with the dimension of the trench 14, determine the capacitance capabilities of the trench capacitor to be completed.

FIG. 4 further illustrates the semiconductor structure 10 subsequent to a removal or planarization process to remove the portions of the first and second conductive layers 16 and 20 and first and second dielectric layers 18 and 22 on the interlayer dielectric layer 12. In illustrative processes, the planarization process includes a CMP process. In some embodiments, a different planarization process, such as etching or grinding, is used to remove the first and second conductive layers 16 and 20 and first and second dielectric layers 18 and 22 from a top surface of the interlayer dielectric layer 12.

FIG. 5 illustrates a fifth intermediate stage of fabrication of the semiconductor structure 10. During this stage, an interlayer dielectric layer 24 is deposited on the semiconductor structure 10. In illustrative embodiments, the interlayer dielectric layer 24 may be directly deposited and/or formed on the semiconductor structure 10. In other illustrative embodiments, an etch stop layer (not shown) may be deposited following by formation of the interlayer dielectric layer 24 on the etch stop layer. The interlayer dielectric layer 24 may include one or more materials as discussed above for interlayer dielectric layer 12. In some embodiments, the interlayer dielectric layer 24 is the same material as interlayer dielectric layer 12. In some embodiments, the interlayer dielectric layer 24 is formed by CVD, PVD, ALD, plasma-enhanced chemical vapor deposition (PE-CVD), spin-on coating, other suitable formation process(es), or combinations thereof.

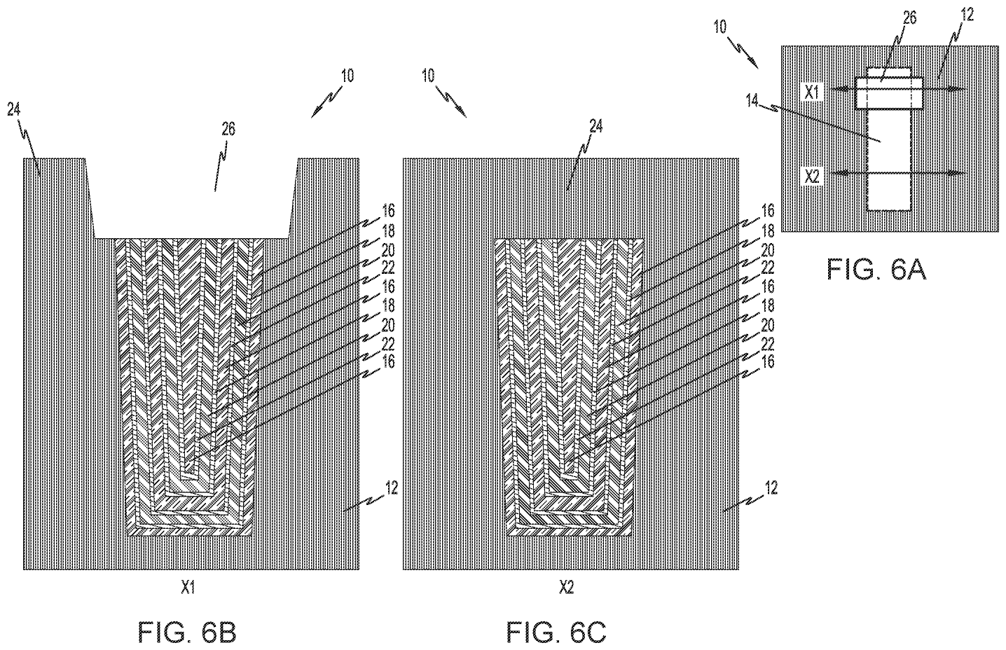

FIGS. 6A-6C illustrate a sixth intermediate stage of fabrication of the semiconductor structure 10. During this stage, a contact opening 26 is formed to extend through the interlayer dielectric layer 24 and expose contact regions on the first and second conductive layers 16 and 20 and first and second dielectric layers 18 and 22. In illustrative embodiments, a contact etch pattern in combination with one or more etching processes such as a plasma etch process, a combination wet/dry etch processes, other suitable etch process(es), or a combination thereof, is utilized to form the contact opening 26.

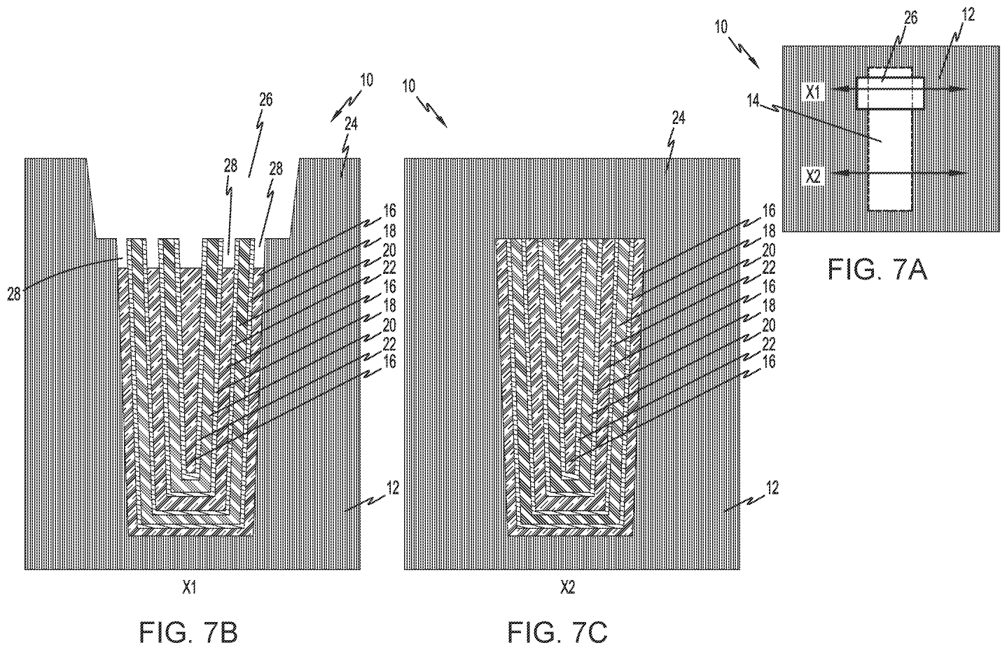

FIGS. 7A-7C illustrate a seventh intermediate stage of fabrication of the semiconductor structure 10. During this stage, one or more etching processes selective to the material of the first conductive layer 16 are carried out to remove the upper portions of the first conductive layers 16 to a predetermined distance. The degree to which the upper portions of the first conductive layer 16 may be removed is selectively controlled by the etching processes. The etching processes can produce voids 28 above the first conductive layers 16 extending to the base adjacent the contact opening 26.

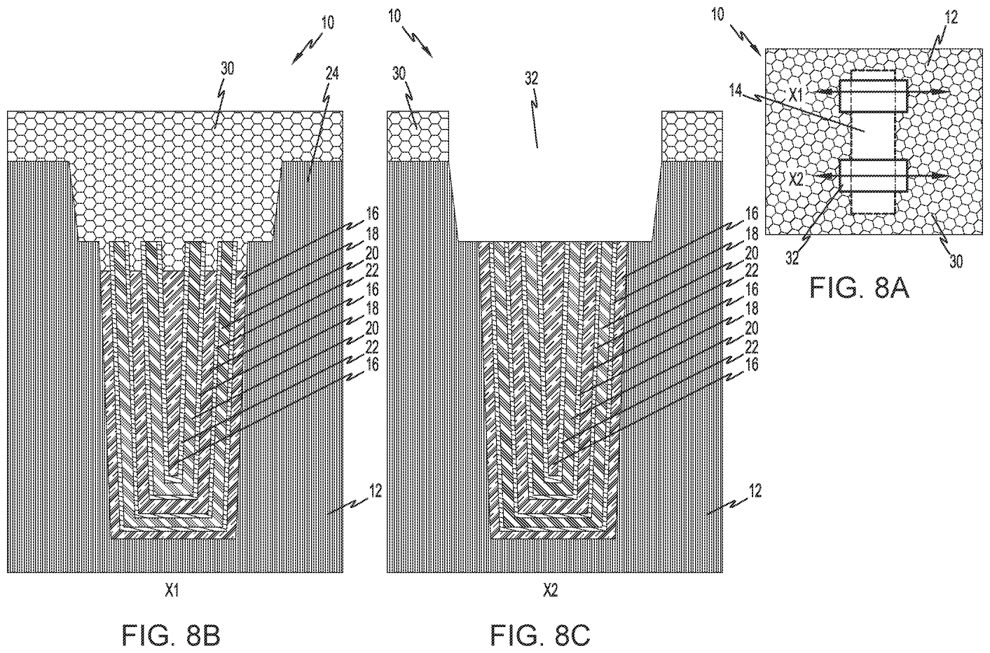

FIGS. 8A-8C illustrate an eight intermediate stage of fabrication of the semiconductor structure 10. During this stage, a masking layer 30 (e.g., an organic planarization layer (OPL)) is deposited, e.g., by spin-on coating, onto the semiconductor structure 10 and into the voids 28 above the first conductive layers 16 and is baked at a suitable temperate ranging from about 100° C. to about 400° C.

Masking layer 30 can be composed of a flowable organic material such as, for example, a spin-on-carbon (SOC). Masking layer 30 fills the trench 14, the contact opening 26 and voids 28, and forms a layer on the interlayer dielectric layer 24. In illustrative embodiments, masking layer 30 is self-leveling and can achieve planarization over the surface topography without the use of etching, CMP, or other conventional planarization techniques. In illustrative embodiments, masking layer 30 may require multiple deposition processes, etching processes or optionally a CMP process to planarize masking layer 30.

Following deposition, masking layer 30 is subjected to a trench or opening patterning procedure, e.g., conventional lithographic and etching processes utilizing, e.g., a reactive ion etching (ME) process (with, e.g., a halogen-based plasma chemistry) to remove at least a segment of masking layer 30 thereby forming a contact opening 32 above the capacitor structure. The contact opening 32 can be spaced from the previously formed contact opening 26 at a predetermined distance.

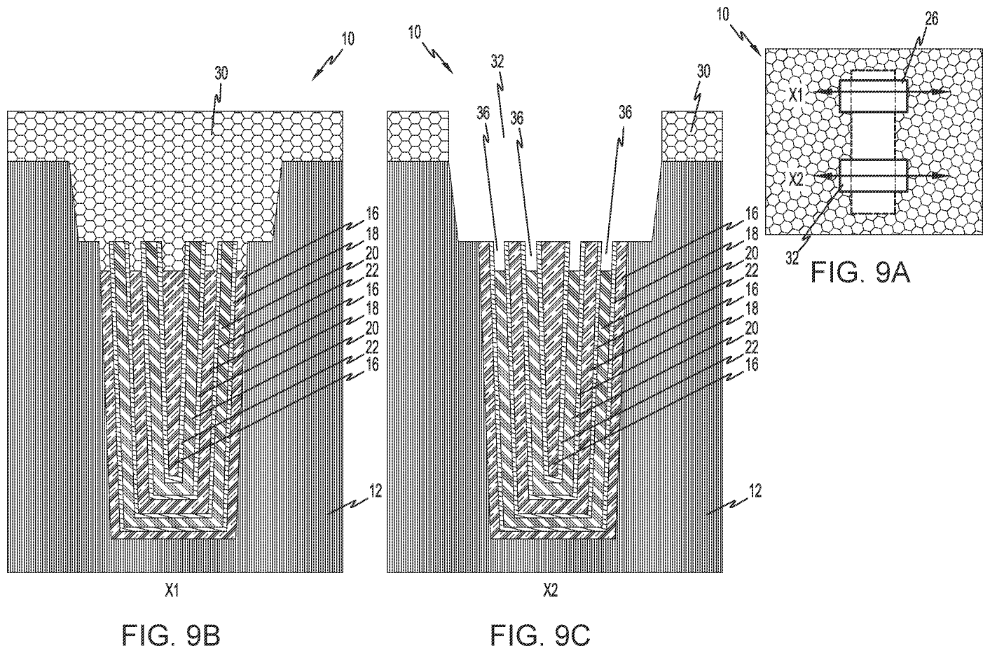

FIGS. 9A-9C illustrate a ninth intermediate stage of fabrication of the semiconductor structure 10. During this stage, one or more etching processes selective to the material of the second conductive layers 20 are carried out to remove an upper portion of the second conductive layers 20 at a predetermined distance. For example, in non-limiting illustrative embodiments, a predetermined distance is at least 5 nm to prevent layer contact to recessed metal breakdown. The degree to which the upper portions of the second conductive layers 20 may be removed is selectively controlled by the etching processes. The etching processes produce second voids 36 above the second conductive layers 20 extending to the base of the contact opening 26. The dimensions of the voids 36 may vary in height and width relative to the voids 28. In other illustrative embodiments, the dimensions of the voids 28 and 36 may be similar.

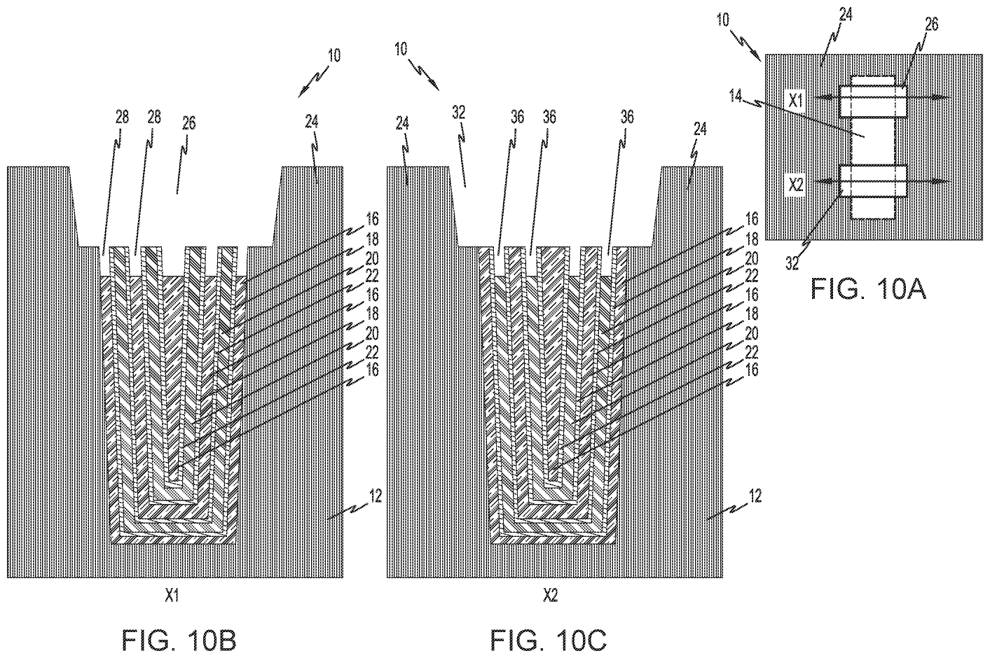

FIGS. 10A-10C illustrate a tenth intermediate stage of fabrication of the semiconductor structure 10. During this stage, the remaining masking layer 30 is removed by, for example, an ash etching process. In illustrative embodiments, the etching material can be an oxygen ash or a nitrogen or hydrogen-based chemistry including, e.g., nitrogen gas or hydrogen gas, or a combination thereof. The ash etching process removes the remaining masking layer 30 with little or no gouging of the underlying components of the semiconductor structure 10.

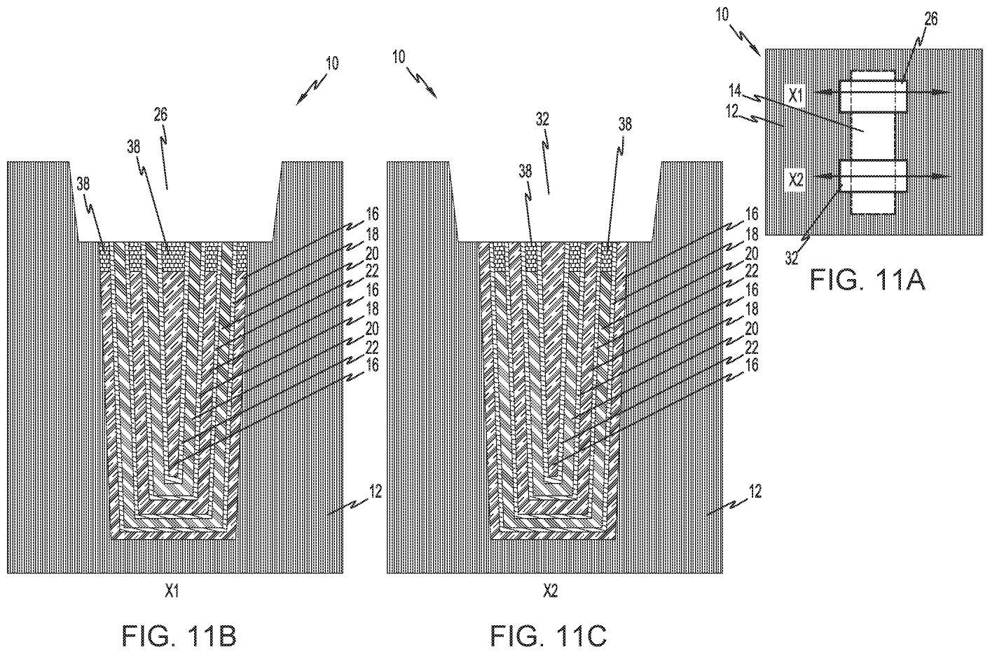

FIGS. 11A-11C illustrate an eleventh intermediate stage of fabrication of the semiconductor structure 10. During this stage, a dielectric fill is deposited on interlayer dielectric layer 24 and within the contact openings 26 and 32 to fill the voids 28 and 36 defined by the removed portions of the first and second conductive layers 16 and 20. The dielectric fill material may be deposited using known dry deposition techniques such as ALD, PVD, CVD. A suitable material for dielectric fill includes, for example, a dielectric material such as SiN, SiO₂, SiOC, SiOCN, SiBCN, SiC, etc.

Next, the dielectric fill is subjected to an etching process, including, for example, an isotropic etching process, which removes the dielectric fill from all exposed surfaces thereby forming inner spacers 38 within the voids 28 and 36 of the first and second conductive layers 16 and 20. Thus, subsequent to the formation of the inner spacers 38, in the first contact opening 26, only the top surfaces of the second conductive layers 20 are exposed and in the contact opening 32 only the top surfaces of the first conductive layers 16 are exposed. Thus, the first and second conductive layers 16 and 20 are isolated from each other by the inner spacers 38 and the dielectric layers 18 and 22. The aforementioned processes thereby form at least part of a capacitor structure including the first and second conductive layers 16 and 20, first and second dielectric layers 18 and 22 and inner spacers 38.

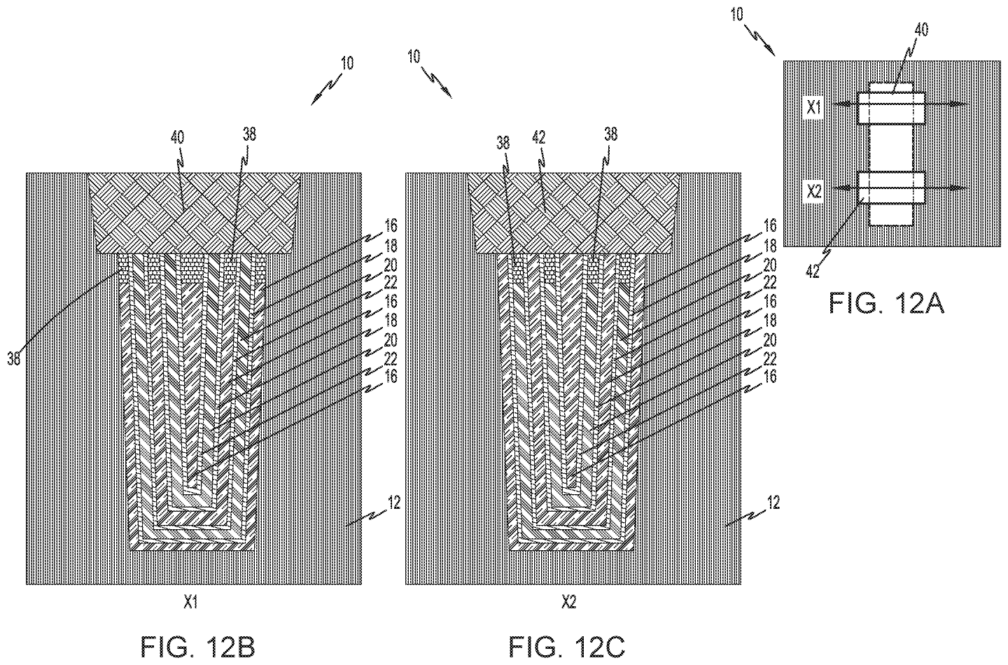

FIGS. 12A-12C illustrate a twelfth intermediate stage of fabrication of the semiconductor structure 10. During this stage, a conductive contact material is deposited to fill the contact openings 26 and 32. In illustrative embodiments, the conductive contact material comprises only a single material. In other illustrative embodiments, a multi-material and/or multi-layer structure is utilized. In illustrative embodiments, a barrier layer (not shown) is initially deposited prior to deposition of the conductive contact material. Suitable conductive contact material includes, for example, conductive material such as, for example, tungsten (W), aluminum (Al), copper (Cu), cobalt (Co), ruthenium (Ru), molybdenum (Mo), or any other suitable conductive material. In some embodiments, the conductive contact material layer is formed using plating, PVD, sputtering, or another suitable formation process. If necessary, any overfill of the conductive contact material layer can be planarized using CMP, grinding, etching or another suitable leaving the contact material layer in the contact openings 26 and 32 to form contacts 40 and 42 on the capacitor structure.

In illustrative embodiments, the first contact 40 is electrically connected to, i.e., in contact with, the second conductive layers 20 and isolated from the first conductive layers 16 at least in part by inner spacers 38 and first and second dielectric layers 18 and 22. In illustrative embodiments, the second contact 42 is electrically connected to, i.e., in contact with, the first conductive layers 16 and isolated from the second conductive layers 20 at least in part by inner spacers 38 and first and second dielectric layers 18 and 22.

In illustrative embodiments, an interconnect layer (not shown) may be deposited over the semiconductor structure 10 and the exposed upper surfaces of the first and second contacts 40 and 42. In some embodiments, an interconnect layer is part of an interconnect structure of an integrated circuit.

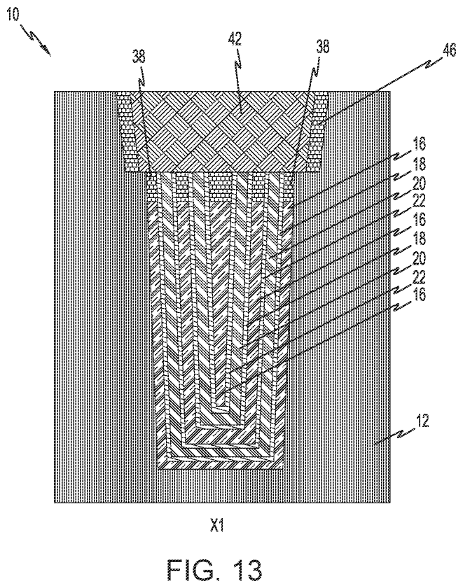

FIG. 13 illustrates an alternate embodiment associated with the eleventh stage of fabrication of the semiconductor structure 10. During this stage, a vertical spacer 46 can be deposited, in addition to inner spacers 38, along the vertical walls of each of the contact openings 26 and 32 prior to depositing the conductive contact material. For example, inner spacers 38 are etched back using, for example, an anisotropic etch back process to form vertical spacer 46. FIG. 13 further illustrates the vertical walls surrounding the second contact 42. The first contact 40 would also contain a similar vertical spacer 46.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a capacitor structure at least partially disposed in a trench of an interlayer dielectric, the capacitor structure comprising first and second electrode layers separated by a dielectric layer, a top surface of the first electrode layer being below a top surface of the second electrode layer and the dielectric layer;
a spacer disposed on the first electrode layer; and
a contact disposed in the trench and connected to the second electrode layer and the spacer.

2. The semiconductor structure according to claim 1, wherein the contact is isolated from the first electrode layer by the spacer.

3. The semiconductor structure according to claim 1, further comprising:
at least two first electrode layers and at least two second electrode layers;
wherein adjacent ones of the first and second electrode layers are separated by the dielectric layer.

4. The semiconductor structure according to claim 3, wherein each of the at least two first electrode layers comprise the spacer disposed on a top surface of each respective first electrode layer.

5. The semiconductor structure according to claim 4, wherein the spacer and the at least two second electrode layers are coterminous with the dielectric layer.

6. The semiconductor structure according to claim 1, wherein the first electrode layer, the second electrode layer and the dielectric layer comprise u-shaped layers.

7. The semiconductor structure according to claim 1, further comprising a sidewall spacer along sidewalls of the trench.

8. The semiconductor structure according to claim 1, wherein the first electrode layer comprises a first material and the second electrode layer comprises a second material different from the first material.

9. The semiconductor structure according to claim 1, wherein the spacer comprises a dielectric material.

10. A semiconductor structure, comprising:
a capacitor structure at least partially disposed in a trench of an interlayer dielectric layer, the capacitor structure comprising first and second electrode layers separated by a dielectric layer, a top surface of the second electrode layer being below a top surface of the first electrode layer and the dielectric layer;
a spacer disposed on the second electrode layer; and
a contact disposed in the trench and connected to the first electrode layer and the spacer.

11. The semiconductor structure according to claim 10, wherein the contact is isolated from the second electrode layer by the spacer.

12. The semiconductor structure according to claim 10, further comprising:
at least two first electrode layers and at least two second electrode layers;
wherein adjacent ones of the first and second electrode layers are separated by the dielectric layer.

13. The semiconductor structure according to claim 12, wherein each of the at least two second electrode layers comprise the spacer disposed on a top surface of each respective second electrode layer.

14. The semiconductor structure according to claim 13, wherein the spacer and the at least two first electrode layers are coterminous with the dielectric layer.

15. The semiconductor structure according to claim 10, wherein the first electrode layer, the second electrode layer and the dielectric layer comprise u-shaped layers.

16. The semiconductor structure according to claim 10, further comprising a sidewall spacer along sidewalls of the trench.

17. The semiconductor structure according to claim 10, wherein the first electrode layer comprises a first material and the second electrode layer comprises a second material different from the first material.

18. The semiconductor structure according to claim 10, wherein the spacer comprises a dielectric material.

19. A semiconductor structure, comprising:
a capacitor structure at least partially disposed in a trench of an interlayer dielectric layer, the capacitor structure comprising a plurality of first and second electrode layers arranged in alternating relation with each other and having a dielectric layer disposed between adjacent first and second electrode layers, wherein the plurality of first electrode layers, the plurality of second electrode layers and the dielectric layer are in a u-shaped configuration, wherein one of the plurality of first electrode layers and the plurality of second electrode layers have a top surface below a top surface of the other one of the plurality of first electrode layers and the plurality of second electrode layers;
a spacer on the top surface of the respective one of the plurality of first electrode layers and the plurality of second electrode layers having the top surface below the top surface of the other one of the plurality of first electrode layers and the plurality of second electrode layers; and
a contact disposed in the trench and connected to the other one of the plurality of first electrode layers and the plurality of second electrode layers and the spacer.

20. The semiconductor structure according to claim 19 wherein the capacitor structure forms at least part of a metal-insulator-metal capacitor.
